(19) United States
(12) Patent Application Publication
(10) Pub. No.: US 2004/0137734 A1
(43) Pub. Date: Jul. 15, 2004

(54) Compositions and processes for nanoimprinting

(75) Inventors: Stephen Y. Chou, Princeton, NJ (US); Lei Chen, Princeton, NJ (US)

Correspondence Address: GLEN E. BOOKS, ESQ., LOWENSTEIN SANDLER PC, 65 LIVINGSTON AVENUE, ROSELAND, NJ, 07068, US

(73) Assignee: PRINCETON UNIVERSITY

(21) Appl. No.: 10/706,757

(22) Filed: Nov. 12, 2003

Related U.S. Application Data
(63) Continuation-in-part of application No. 10/301,475, filed on Nov. 21, 2002.
Application No. 10/301,475 is a continuation of application No. 09/430,602, filed on Oct. 29, 1999, now Pat. No. 6,518,189.
Application No. 09/430,602 is a continuation-in-part of application No. 09/107,006, filed on Jun. 30, 1998, now Pat. No. 6,309,580.
Application No. 09/107,006 is a continuation-in-part of application No. 08/558,809, filed on Nov. 15, 1995, now Pat. No. 5,772,905.
(60) Provisional application No. 60/425,587, filed on Nov. 12, 2002.

(51) Int. Cl. H01L 21/302; H01L 21/461

(52) U.S. Cl. 438/689

(57) ABSTRACT

The present invention is directed to new nanoimprint resist and thin-film compositions for use in nanoimprinting lithography. The compositions of the present invention permit economical high-throughput mass production, using nanoimprint processes, of patterns having sub-200 nm, and even sub-50 nm features.

This application is a continuation-in-part of U.S. Ser. No. 10/301,475, filed on Nov. 21, 2002, which is a continuation of U.S. Ser. No. 09/430,602, filed Oct. 29, 1999, now U.S. Pat. No. 6,518,189, which is a continuation-in-part of U.S. Ser. No. 09/107,006, filed Jun. 30, 1998, now U.S. Pat. No. 6,309,580, which is a continuation-in-part of U.S. Ser. No. 08/558,809, filed Nov. 15, 1995, now U.S. Pat. No. 5,772,905, each of which patents and patent applications are hereby incorporated herein by reference in their entirety. This application also claims benefit of U.S. Provisional Application Serial No. 60/425,587, filed Nov. 12, 2002, incorporated by reference herein in its entirety.

### FIELD OF THE INVENTION

The present invention relates to compositions for use in nanoimprinting processes, nanoimprinting apparatus, and nanoimprinting processes. The present invention also relates to processes of using moldable compositions that create patterns with ultra fine features in thin films carried on substrate surfaces.

### BACKGROUND

Lithography, particularly photolithography, is used to fabricate semiconductor-integrated electrical circuits; integrated optical, magnetic, mechanical circuits; and microdevices. Lithographic pattern formation involves chemically treating specific regions of a thin film carried on a substrate then removing either the treated or untreated regions as appropriate, for example, by dissolving in a processing solvent. In subsequent steps, the pattern is replicated in the substrate or in another material. In combination with traditional resist imaging, lithography can be used to manufacture printing plates and resist images. The thin film, which accepts a pattern or image during the lithographic process, is often referred to as resist. The resist may be either a positive resist or a negative resist. A positive photoresist becomes more soluble in the processing solvent where irradiated, while a negative resist becomes insoluble where irradiated. A typical lithographic process for integrated circuit fabrication involves exposing or irradiating a photoresist composition or film with a radiation or particle beam, such as light, energetic particles (e.g., electrons), photons, or ions by either passing a flood beam through a mask or scanning a focused beam. The radiation or particle beam changes the chemical structure of the exposed area of the film, so that when washed or immersed in a processing solvent, either the exposed or the unexposed areas of the resist dissolve. Lithographic resolution is limited by the wavelength of the particles, the resolution of the beam, the particle scattering in the resist and the substrate, and the properties of the resist. There is an ongoing need in art of lithography to produce smaller pattern sizes while maintaining cost efficiency. Particularly, there is a great need to develop low-cost technologies for mass-producing sub-50 nm structures. As used herein, the term “sub-xx nm features”, wherein xx is a number, refers generally to a plurality of structures having at least one dimension less than xx nm. As used herein, the term “sub-xx nm features”, wherein xx is a number, refers generally to a plurality of structures having at least one dimension less than xx nm. Such developments will have an enormous impact in many areas of engineering and science.

Numerous technologies have been developed to service these needs, but they all suffer drawbacks and cannot be used to mass produce sub-50 nm lithography at a low cost. Electron beam lithography has demonstrated 10 nm lithography resolutions. A. N. Broers, J. M. Harper, and W. W. Molzen, Appl. Phys. Lett. 33, 392 (1978) and P. B. Fischer and S. Y. Chou, Appl. Phys. Lett. 62, 2989 (1993). But using this technology to mass produce sub-50 nm structures is economically impractical due to inherent low throughput. X-ray lithography, which can have a high throughput, has demonstrated 50 nm lithography resolution. K. Early, M. L. Schattenburg, and H. I. Smith, Microelectronic Engineering 11,317 (1990). But X-ray lithography devices are expensive. X-ray lithography has not been used to commercially mass produce sub-50 nm structures. Lithography based on scanning probes has produced sub-10 nm structures in a very thin layer of materials. But, the practicality of such lithography as a manufacturing tool is not apparent.

Another nanostructure manufacturing process is refereed to in the art as nanoimprinting or nanoimprint lithography, which involves compressive patterning of deformable films coated on a substrate by way of a mold having protrusions and recesses. See for example, U.S. Pat. Nos. 5,772,905 and 6,309,580. The thickness of the film under the protruding feature is thinner than the thickness of the film under the recess. Thus, a relief is formed in the thin film. The relief conforms the mold's features. The relief is processed such that the thinner portion of the film is removed thereby exposing the underlying substrate in a pattern complementary to the mold. The relief patterns so produced can be reproduced in the substrate or in another material.

The patterns formed in nanoimprint lithography are defined by the mold instead of any radiation exposure. Nanoimprint lithography can eliminate many resolution limitations imposed in conventional lithography, such as wavelength limitation, backscattering of particles in the resist and substrate, and optical interference.

This low-cost mass manufacturing technology and has been around for several decades. Using nanoimprint technology, features on the order of 1 micrometer have been routinely imprinted in plastics. Compact disks, which are based on imprinting of polycarbonate, are one example of the commercial use of this technology. Other examples are imprinted polymethylmethacrylate (PMMA) structures with a feature size on the order to 10 micrometers for making micromechanical parts. M. Harmening et al., PROCEEDINGS IEEE MICRO ELECTRO MECHANICAL SYSTEMS, 202 (1992). Molded polyester micromechanical parts with feature dimensions of several tens of microns have also been used. H. Li and S. D. Senturia, PROCEEDINGS OF 1992 13TH IEEE/CHMT INTERNATIONAL ELECTRONIC MANUFACTURING TECHNOLOGY SYMPOSIUM, 145 (1992). But imprint technology has not been able to provide 25 nm structures with high aspect ratios.

Since nanoimprint lithography is based on the deformation of the polymer resists by a mold instead of changing the chemical properties of the resists in photolithography (E. Reichmanis and L. F. Thompson, 89 CHEM. REV. 1273-1289 (1989)), it is necessary to develop the specific polymer resist compositions that can be easily deformed with good viscose flow ability by mold on a substrate and can survive on the substrate after mold separation. Disadvantageously, the thin-film compositions used in standard nanoimprinting processes have physical properties that cause deformities that decrease resolution. Stress is caused when higher temperatures are used to increase the polymeric film's flowability so that it can flow into the nanomold. As used herein, the term “nanomold” generally refers to a mold having a plurality of structures having at least one dimension less than 200 nm. On the other hand, if the temperature is lowered, the film does accurately conform to the small features of the mold because of decreased flowability.

The requirements for nanoimprint lithography materials (“nanoimprint resists”) are quite different than polymeric materials that are typically used in traditional plastics molding techniques, such as injection molding. For example, nanoimprint resists typically require the ability to be processed into uniform thin-films on substrates. In addition, the rheology (i.e., flow characteristics) of polymeric materials deposited as thin polymeric films on surfaces is oftentimes quite different that the rheology of bulk polymeric materials.

U.S. Pat. No. 5,772,905 discloses the use of polymethylmethacrylate (“PMMA”) as a nanoimprint resist, which is advantageously spin castable on a silicon wafer, has good mold release properties and has low thermal shrinkage. The disclosed nanoimprint process requires heating of the spin coated PMMA nanoimprint resist to temperatures (ca. 200° C.) substantially higher than the glass transition temperature (“Tg”) of PMMA (ca. 105° C.) to soften the resist to enable nanoimprinting. The nanoimprint mold is removed after cooling the nanoimprint resist below Tg. This heating and cooling disadvantageously requires process time and can lead to alignment and registration problems of the process equipment arising from thermal expansion and contraction. The need therefore exists to develop nanoimprint resists that overcome these problems.

U.S. Pat. No. 6,309,580 the discloses nanoimprint lithography wherein the mold is pre-treated with a release material that facilitate mold removal and thereby enhance image resolution. Use of the release material also protects the mold so that it can be used repeatedly without showing wear of its fine features. After the relief is processed, the exposed portions of the substrate's surface have sub-200 nm features. Because mold pretreatment is an additional step that is preferably eliminated from the nanoimprint lithography process to increase manufacturing throughput, the need therefore exists to develop nanoimprint resists that provide enhanced image resolution without the need to pretreat the nanomolds.

Accordingly, there is a continuing need for additional improvements in processes, apparatus, materials, and protocols for use in nanoimprint lithography. For example, there is need for new thin-film compositions for use in nanoimprint technology that overcome the above-mentioned problems. Thus, there is a need to provide nanoimprint resists that do not require extensive heating and cooling and which release well from untreated molds.

### SUMMARY OF THE INVENTION

In overcoming the problems associated with nanoimprint resists that do not require extensive heating and cooling and which release well from untreated molds, the present invention provides, inter alia, methods for forming patterns in a film carried on a substrate. In various aspects of the present invention, there are provided methods of:

obtaining a mold of a material, which mold is hard relative to the film, the film including a polymeric composition capable of being deformed by said mold at a temperature of less than 200° C.;

the mold having first and second protruding features spaced apart from each other and a recess formed thereby, the first and second features and the recess having a shape forming a mold pattern and providing at least one mold pattern lateral dimension which is less than 200 nm;

urging the mold into the film under a molding pressure;

the thickness of the film under the protruding features of the mold being reduced, thereby forming the mold pattern in the film;

removing the mold from the film; and

removing from the film the areas of reduced thickness, thereby exposing portions of the surface of the substrate which underlie the thin region such that the exposed portions of the surface of the substrate substantially replicate the mold pattern and have at least one lateral dimension which is less than 200 nm.

In further aspects of the invention, there are provided methods of forming a plurality of structures having at least one dimension less than 200 nm, which includes the step of imprinting a nanoimprint resist using a mold, said nanoimprint resist having a polymeric composition capable of being deformed by said mold at a temperature of less than 200° C. In this aspect of the present invention, the polymeric composition is capable of retaining the plurality of structures upon removal of said mold.

Within additional aspects of the invention, there are provided thin films having a nanoimprint resist including a polymeric composition capable of being deformed by a mold at a temperature of less than 200° C., the mold being capable of forming a plurality of structures having at least one dimension less than 200 nm. In this aspect of the invention, the polymeric composition is capable of retaining said plurality of structures upon removal of said mold.

In yet other aspects of the invention, there are provided nanoimprint resists including a polymeric composition capable of being deformed by a mold at a temperature of less than 200° C., the mold being capable of forming a plurality of structures having at least one dimension less than 200 nm. In this aspect of the invention, the polymeric composition is capable of retaining said plurality of structures upon removal of said mold.

In various aspects of the present invention, new thin-film compositions are provided for use in nanoimprinting lithography. The compositions of the invention permit economical high-throughput mass production, using nanoimprint processes, of patterns having sub-50 nm features. Various compositions of the invention are selected from: (a) thermoplastic materials that are sufficiently soft at ambient conditions, or which can soften sufficiently upon additional heating to flow into the nanomold features (that thermoplastic polymer may be further polymerizable, crosslinkable, graft-linkable, or a combination thereof); and (b) liquid or flowable compositions (e.g., polymers, oligomers, monomers, cross-linking agents, lubricants and plasticizers) that can flow into the features of a nanomold, and which can be subsequently hardened using chemical means (e.g., cross-linking, polymerization, or both) or using thermophysical means (e.g., cooling through a first order transition such as known in block copolymers, or crystallization, or both; or cooling through a second order transition, such as the glass transition); or a combination of both chemical and thermophysical means.

The compositions of several aspects of the invention include plasticizers, internal release agents, and other additives. The use of the plasticizers and internal release agents enable low processing temperatures and good mold-surface release properties. Other additives can be included in the compositions of the invention to improve resist stability and other physical and chemical properties of the resist, including e.g., rheology control additives and antioxidants. The compositions of the invention are useful for forming micro- and nano-replications. As used herein, the term “micro-replication” refers to relief surface patterns capable of transferring features greater than about 200 nm. As used herein, the term “nano-replication” refers to relief surface patterns capable of transferring features smaller than about 200 nm.

In various aspects of the present invention, the compositions are provided as single or multiple layer structures. In this embodiment, a pattern can be imprinted in one layer and then is transferred to the lower layer by etching or other methods.

In certain aspects, there are provided compositions that permit a high throughput mass production method for generating patterns having sub-25 nm features, which is unattainable with methods described in the prior art. The flowability and stability of a variety of compositions in molds having different feature size patterns provided by these aspects of the invention is particularly noteworthy. Accordingly, in contrast to conventional lithography, nanoimprint lithography processes involve low temperatures. Since in nanoimprint processes, the thin-film compositions desirably flow into the mold, they desirably have good low-temperature flowability. The excellent flowability of compositions of the invention at low temperature is much improved over prior-art thin film compositions.

In further aspects of the invention, the compositions of the invention provide highly uniform thin films on substrates. Such high uniformity greatly improves nanoimprint processes. The compositions of the invention further improve nanoimprinting processes because they exhibit good adhesion to the substrate while, at the same time, exhibit good release properties from the mold.

### DETAILED DESCRIPTION OF ILLUSTRATIVE EMBODIMENTS

The term “polymer” used herein denotes a molecule having two or more units derived from the same monomer component, so that “polymer” incorporates molecules derived from different monomer components to for form copolymers, terpolymers, multi-component polymers, graft-co-polymers, block-co-polymers, and the like.

The term “glassy” used herein denotes the thermodynamic state of a polymer below its glass transition temperature.

The term “units derived from” used herein refers to polymer molecules that are synthesized according to known polymerization techniques wherein a polymer contains “units derived from” its constituent monomers.

The term “molecular weight” used herein refers to the weight average molecular weight of polymer molecules as determined by the gel permeation chromatography method.

The term “graftlinker” used herein refers to multi-functional monomers capable of forming multiple covalent bonds between polymer molecules of one type with polymer molecules of another type.

The term “crosslinker” used herein refers to multi-functional monomers capable of forming two or more covalent bonds between polymer molecules of the same type.

The term “alkyl (meth)acrylate” used herein refers to both alkyl acrylate and alkyl methacrylate monomer compounds.

The term “parts” used herein is intended to mean “parts by weight”. Unless otherwise stated, “total parts by weight” do not necessarily add to 100.

The term “weight percent” used herein is intended to mean “parts per hundred by weight” wherein the total parts add to 100.

All ranges described herein are inclusive and combinable.

The methods of the present invention for forming a pattern having features small than 200 nanometers in a film carried on a substrate typically involve a variety of steps which include obtaining a mold of a material, which mold is hard relative to the film, the film including a polymeric composition capable of being deformed by said mold at a temperature of less than 200° C. In these methods, the mold typically has first and second protruding features spaced apart from each other and a recess formed thereby. The first and second features and the recess typically have a shape that is capable of forming a mold pattern and providing at least one mold pattern lateral dimension which is less than 200 nm. In these methods, the mold is urged into the film under a molding pressure, thereby reducing the thickness of the film under the protruding features of the mold, which forms the mold pattern in the film. Further steps of removing the mold from the film; and removing from the film the areas of reduced thickness, exposes portions of the surface of the substrate which underlie the thin region such that the exposed portions of the surface of the substrate substantially replicate the mold pattern and have at least one lateral dimension which is less than 200 nm. Additional details pertaining to nanoimprint lithography processes are provided in U.S. Pat. Nos. 5,772,905; 6,309,580; 6,482,742; 6,518,189; U.S. Pat. App. Pub Nos. 2002/0132482A1; 2002/0167117A1; 2003/0034329A1; 2003/0080471A1; 2003/0080472A1; 2003/0170995A1; 2003/0170996A1; and Int. App. Nos. PCT/US01/21005 and PCT/US03/08293, the disclosures of which are incorporated by reference herein in their entirety.

Suitable polymeric compositions capable of being deformed by said mold at a temperature of less than 200° C. can be formulated from a variety of polymers, oligomers, monomers, cross-linkers, graft-linkers, diluents, initiators, curing agents, and other additives known in the polymer art. Typically the polymeric compositions will be relatively soft at temperatures less than 200° C., such as by having a glass transition temperature less than 200° C. or being in a liquid state at a temperature less than 200° C. Polymeric compositions that have a liquid or soft state at use temperatures of the nanoimprint resist may also be used. Such liquid or soft polymeric compositions will typically be subject to a hardening condition prior to their subsequent in nanoimprint lithography. Examples of suitable hardening conditions include chemical reactions, such as cross-linking reactions, graft-linking reactions, condensation reactions, acid-base reactions, polymerization, as well as any a combination thereof. Examples of suitable hardening conditions also include thermophysical reactions such as crystallization and ordering upon heating or cooling of the polymeric composition. Combinations of chemical and thermophysical reactions are also envisioned as providing suitable polymeric compositions capable of being deformed by said mold at a temperature of less than 200° C.

Suitable polymeric compositions used in various embodiments of the present invention include homopolymers, copolymers, a random co-polymers, block co-polymers, graft co-polymers, telechelic polymers, star polymers, as well as dendrimers, e.g., the so-called “starburst” polymers, as well as any combination thereof. Suitable polymers typically include: poly(C₁-C₂₀ alkyl acrylates) and poly(C₁-C₂₀ alkyl methacrylates) (both of which are also referred together to as C₁-C₂₀ alkyl (meth)acrylates), typical examples being poly(methyl methacrylate), poly(octadecyl methacrylate), poly(methylacrylate), poly(n-butyl acrylate), poly(butyl methacrylate), poly(isobutyl methacrylate); copolymers including C₁-C₂₀ alkyl (meth)acrylate units, typical examples being poly(vinyl stearate)/poly(methyl methacrylate), poly(methylhexadecylsiloxane)/poly(methyl methacrylate), poly(octadecyl methacrylate)/poly(methyl methacrylate), poly(butyl methacrylate-co-isobutylmethacrylate), poly(butyl methacrylate-co-methyl methacrylate); polycarbonates, such as poly(bisphenol-A carbonate); polysiloxanes such as poly(methylhexadecylsiloxane); various vinyl polymers such as poly(vinylacetate), poly(vinyl stearate); various alkyl oxide polymers such as poly(ethylene oxide) and poly(propylene oxide); polycaprolactone; styrenic polymers such as poly(styrene), poly(α-methylstyrene), as well as styreneic-containing copolymers such as poly(dimethylsiloxane-co-alpha-methylstyrene); graft-co-polymers such as poly(ethylene-covinylacate)-graft(t-maleic anhydride); halide containing polymers and copolymers such as poly(vinyl chloride), poly(vinylidene fluoride), poly(chlorotrifluoroethylene), poly(dichloroethylene), poly(vinyl chloride-co-vinylacetate), poly(vinyl chloride-co-isobutylvinylether), poly(chlorotrifluorethylene-co-vinylidene fluoride); and any blend, graft, or block of a combination of one or more polymers.

Suitable polymeric compositions also can include thermoset resins. Many commercially available thermoset resins which can be used in the present invention include: alkyd resins, allyl diglycol carbonate resins, diallyl isophthalate resins, diallyl phthalate resins, melamine resins, melamine/phenolic resins, phenolic resins, vinyl ester resins; epoxy resins; unsaturated polyester resins; cyanoacrylate resins; melamine-formaldehyde resins; polyurethane resins; polyimide resins; polyphenol resins; and combinations thereof.

Suitable polymeric compositions of the present invention may also include one or more oligomers. As used herein, the term “oligomer” refers to a compound comprised of from two to about five monomeric units, all of which can be the same of different. Suitable oligomers include those having reactive functionalities as well as non-reactive functionalities. Examples of suitable reactive and non-reactive oligomers composed of up to five monomeric units of C₁-C₂₀ alkyl (meth)acrylates are provided in U.S. Pat. No. 6,306,546, the disclosure of which is incorporated by reference herein in its entirety. Other suitable oligomers include reactive polysiloxane oligomers, reactive or any combination thereof.

Suitable polymers and oligomers can also include the so-called “liquid rubbers” (“LR”), which are widely used in thermosetting materials. Suitable LRs are composed of flexible polymer chains that have at least one non-functional aromatic terminal end-group. While polymer chain flexibility is provided by a glass transition temperature (Tg) less than about 25° C., it is often typical that the Tg will be less than 10° C., more typically less than 0° C., even more typically less than −20° C., and further typically less than −40° C. Suitable LRs typically have low viscosities in uncured liquid resin formulations. Suitable LRs also tend to be miscible in uncured liquid resin formulations, however immiscible formulations can also be used. In certain embodiments, the LRs may phase separate upon curing (crosslinking) when provided with thermoset resins in the polymeric composition. Such phase separation typically forms rubbery microdomains in the polymeric matrix of the thermosetting resin. In other embodiments, however, it is desirable that such phase separation is minimized or avoided. Various types of LRs are disclosed in Mulhaupt, R., “Flexibility or Toughness?—The Design of Thermoset Toughening Agents”, Chimia 44 (1990), pp. 43-52. Examples of liquid rubbers are also described in European Patent Application No. EP 1,270,618 to LaFleur, which are composed of flexible polymer chains that have at least one non-functional aromatic terminal end-group.

In certain embodiments of the present invention, the polymers and oligomers may contain functional groups. In these embodiments, the functional groups can be located anywhere on the molecule, including at their ends, denoted “terminally functional” or “functionally terminated”. Commercially-available functionally terminated LRs include carboxy-terminated copolymers of butadiene and acrylonitrile monomers, known as “CTBN” resins, and amino-terminated copolymers of butadiene and acrylonitrile monomers, known as “ATBN” resins. Similar copolymers end-functionalized with vinyl groups and epoxy groups are also known as “VTBN” and “ETBN”, respectively. A particular useful composition includes an epoxy resin blended with one or more oligomers.

In related embodiments of the invention, there are provided methods of forming a plurality of structures having at least one dimension less than 200 nm, which includes the step of imprinting a nanoimprint resist using a mold, the nanoimprint resist having a polymeric composition capable of being deformed by the mold at a temperature of less than 200° C. In these embodiments, the polymeric compositions are capable of retaining a plurality of structures upon removal of the mold.

In these and other embodiments, the polymeric compositions are capable of being deformed by the mold, typically at a temperature of less than 200° C., more typically at a temperature of less than about 150° C., and even more typically at a temperature of less than about 100° C. Suitable polymeric compositions typically include a photocurable polymeric composition, a thermoplastic polymeric composition, a thermosettable polymeric composition, or any combination thereof.

As used herein, the term “photocurable” is meant to refer to compositions in which a chemical reaction is brought about upon the application of a photon, such as light, e.g., ultraviolet (“UV”) light. Suitable photocurable compositions typically include at least one monomer and one photocuring agent. Any one monomer, or combination of monomers, as herein described may be suitably used. Suitable photocuring agents include polymerization initiators, cross-linkers and graft-linkers that are activated by radiation, typically ultraviolet light. Suitable photocurable polymeric compositions will typically cure upon the exposure of radiation within the range of about 1 millisecond to about 2 seconds, although curing times are envisioned as capable of being outside this range. Suitable photocurable polymeric compositions have viscosities typically greater than 100 centipoise (cps), although viscosities are envisioned as capable of being outside this range. The photocurable polymeric compositions also desirable have suitably low energy of adhesions to the mold surfaces to provide ready release of the cured nanoimprint resist from the mold. Suitably low energy of adhesions can be provided by choosing polymeric compositions that have relatively low interaction energies for the mold surfaces, for example by the inclusion of silicon-containing or fluorine-containing components in the polymeric composition. This can be suitably provide by selecting suitable components of the polymeric composition, e.g. polymer, monomer, oligomer, and photocuring agent that provide low energies of adgesion. More typically, an internal mold release agent is included in the polymeric compositions. Examples of internal mold release agents are provided herein. An examples of a suitable photocuring agents includes IrgaCure 184. When a crosslinking agent (“cross-linker”) is included in the polymeric compositions, the polymeric compositions typically crosslink in less than about 2 seconds. Desirable photocurable polymeric compositions are capable of crosslinking in the presence of oxygen.

In one embodiment of the present invention, the polymeric composition includes about 80 weight percent to 90 weight percent of an acrylic monomer, such as methyl methacrylate monomer, about 10 to 20 weight percent of an oligomer, such as derived from a siloxane, a dimethylsiloxy copolymer, isobornyl methacrylate, MATS, TMPTA, or a silicon-containing oligomer, such as an acrylic siloxane; from about 0.01 to about 2 weight percent of a crosslinker, such as IrgaCure 819; and a photoinitiator, such as IrgaCure 184. In this embodiment, the large weight fraction of monomer typically acts like a solvent for dissolving all of the components. Typically, the composition has a viscosity of at least about 2 poise at 25° C., typically in the range of about 10 poise to about 30 poise.

Suitable thermoplastic polymeric compositions typically include any of the polymers described hereinabove. Suitable thermoplastic polymers typically having a glass transition temperature less than 100° C. Suitable thermoplastic polymers typically have a weight average molecular weight in the range of about 5,000 g/mol and 1,000,000 g/mole, although suitable thermoplastic polymers may have weight average molecular weights outside of this range. Examples of suitable thermoplastic polymers typically include any of the non-crosslinked or lightly crosslinked polymers described herein.

In other embodiments of the invention, there are provided thin films having a nanoimprint resist including a polymeric composition capable of being deformed by a mold at a temperature of less than 200° C., the mold being capable of forming a plurality of structures having at least one dimension less than 200 nm. In this aspect of the invention, the polymeric composition is capable of retaining the plurality of structures upon removal of the mold.

In other embodiments of the invention, there are provided nanoimprint resists including a polymeric composition capable of being deformed by a mold at a temperature of less than 200° C., the mold being capable of forming a plurality of structures having at least one dimension less than 200 nm. In this aspect of the invention, the polymeric composition is capable of retaining the plurality of structures upon removal of the mold.

In one embodiment, the present invention provides nanoimprint resist compositions and thin films for use in nanoimprinting lithography to form patterns on a substrate. The compositions of the present invention permit formation of thin-film patterns in the form of nanoscale features, such as holes, pillars, or trenches. These nanoscale features typically have a minimum size of about 25 nm, a depth over about 100 nm, a side wall smoothness better than about 3 nm, and corners with near perfect 90 degrees angles. The compositions of the present invention can be used in nanoimprint processes to form sub-10 nm structures having a high aspect ratio.

One embodiment of the present invention includes a material deposition and a lift-off process for fabricating 100 nm wide metal lines of a 200 nm period and 25 nm diameter metal dots of 125 nm period. The resist pattern that can be created using the present invention can also be used as a mask to etch nanostructures (features having dimensions less than 1000 nm, preferably less than 500 nm) into a substrate. The compositions of the invention also permit manufacture of larger film surface areas, while still retaining high resolution and lowered waste due to damage of the film when removed from the nanomold. The present invention can also is capable of improving the nanoimprint process to even larger area mold (over 6 inch) with high quality.

In certain embodiments of the present invention, the nanoresist compositions present include: (A) one or more materials from the group of polymers, oligomers, and monomer mix. Optionally, the compositions of the invention may further comprise other additives as needed, such as one or more of (B) one or more plasticizers; (C) one or more internal mold release agents; and (D) other additives, such as compatibilizers, lubricants, and stabilizers.

In other embodiments, a variety of nanoimprint resist compositions are provided by the present invention for a variety of nanoimprint process schemes. For example, for a thermal imprint, where the temperature is used to control the viscosity and flowability of moldable materials, a photoinititor is typically not required, although a combination of thermal and photoinitiator can be used, for example photo-initiator, thermal initiator, or both, can be used for post-imprint UV exposure or bake for improving mechanical strength. In these embodiments, crosslinking agents can also be added to crosslink the nanoimprint resist compositions.

In various nanoimprint processes, it is also possible for one to use either a single layer nanoimprint composite or multi-layers of composites in the present inventions. In the multilayer embodiments, the layer properties can be the same or different than each other. For example, patterns created at the top layer can be transferred to the underlayers by etching or other conventional techniques of pattern transfer known in the art of chemical microelectronics lithography.

Component Group A: One or More Materials From the Group of Polymers, Oligomers, and Monomer Mix

This category includes different polymers with the structures of homopolymers or co-polymers, which can be random, block, alternative, grafted, telechelic, star, dendrimer, e.g., hyperbranched polymers and oligomers; polymers having different molecular weights; oligomers; different monomers; the mix from polymers, oligomers, and monomers; non-reactive system; reactive system (the materials become hard or non-flowable during or after the process by UV, thermal and other treatments); polymer blends (of the above systems); materials that are resistive to reactive ion etching; moldable polymers and reactive oligomers (monomers); as well as any combinations thereof.

Examples of polymers having a different main chain backbone, suitable for use in compositions of the invention, include, but are not limited to, poly(methyl methacrylate) (PMMA), poly(bisphenol-A carbonate), and poly(methylhexadecylsiloxane).

Examples of suitable polymers having different side chains suitable for use in the invention include, but are not limited to, PMMA, poly(methylacrylate), poly(n-butyl acrylate), poly(octadecyl methacrylate), poly(isobutyl methacrylate), and poly(butyl methacrylate)

Typically, Suitable polymeric components will typically have a weight average molecular weight in the range of from about 1,000 g/mol to about 1,000,000 g/mol, typically in the range of from about 5,000 g/mol to about 200,000 g/mol. More typically in the range of from about 10,000 g/mol to about 100,000 g/mol, and even more typically in the range of from about 20,000 g/mol to about 50,000 g/mol. Examples of polymers having different weight average molecular weights suitable for use in the invention include, but are not limited to, poly(vinylacetate 110,000 g/mol) and poly(vinylacetate 650,000 g/mol).

A variety of polymer morphologies are also suitable for use in the present invention, for example, crystalline, semi-crystalline, amorphous, glassy, as well as containing microphase separated regions that are commonly found in ordered block and graft copolymers. Examples of polymers having different morphologies suitable for use in the invention include, but are not limited to, poly(vinyl stearate) (PVS), poly(ethylene oxide), polycaprolactone, and poly(α-methylstyrene). Advanced polymeric architectures (such as graft copolymers, block copolymers, comb polymers, star polymers, starburst polymers, etc.) each having two or more polymer chains or chain fragments are also envisioned. In the case of advanced polymeric architectures such as these, it is typical that up to all of the chain ends can contain non-functional aromatic end-groups.

Examples of suitable polymer blends suitable for use in the invention include, but are not limited to, PVS/PMMA; poly(methylhexadecylsiloxane)/PMMA; and poly(octadecyl methacrylate)/PMMA.

Examples of suitable random co-polymers suitable for use in the invention include, but are not limited to, poly(butyl methacrylate-co-isobutylmethacrylate); poly(butyl methacrylate-co-methyl methacrylate); poly(dimethylsiloxane-co-alpha-methylstyrene); copolymers of isobomyl (meth)acrylate; copolymers of isobutyl methacrylate; poly(ethylene-co-vinylacate)-graft(t-maleic anhydride); poly(vinyl chloride-co-vinylacetate); poly(vinyl chloride-co-isobutylvinylether); and poly(chlorotrifluorethylene-co-vinyldiene fluoride).

Monomers suitable for use in the present invention include “High-Tg” as well as “Low-Tg” monomers. Low-Tg monomers are typically selected from the following group: C₁ to C₂₀ alkyl acrylate monomers such as butyl acrylate, ethyl acrylate, n-octyl acrylate, and 2-ethylhexyl acrylate; diene monomers such as butadiene and isoprene; siloxane monomers such as dimethylsiloxane, vinyl acetate monomers; and copolymers thereof. Examples of high-Tg monomers typically include C₁ to C₈ alkyl methacrylates, isobornyl methacrylate, styreneics, acrylonitrile, and imides.

In certain embodiments, it is desirable that the weight fraction of the low Tg monomers in the polymeric compositions be selected so that the nanoimprinting layer is not too soft. Accordingly, in instances where harder nanoimprinting layers are sought, it is desirable that the weight fraction of the C₁ to C₂₀ alkyl acrylate monomers typically comprise no more than 50, more typically no more than 40, even more typically no more than 30, and most typically no more than 20 weight percent of the polymerized polymeric composition.

Various co-monomers that may also be incorporated in the polymeric compositions of the present inventions, include one or more ethylenically unsaturated monomers from one or more of the following monomer classes: (meth)acrylic acids; (meth)acrylonitriles; (meth)acrylamides; 2-(perfluoroalkyl)ethyl (meth)acrylates; 2-(perhaloalkyl)ethyl (meth)acrylates; C₁-C₂₀ alkyl (meth)acrylates; alkyl(ethyleneoxy)ₙ(meth)acrylates; amino (meth)acrylates; aryl (meth)acrylates including multiple rings and substituted rings; conjugated dienes; silanes; siloxanes; vinyl aromatics, including multiple rings and substituted rings; vinyl benzoic acids; vinyl ester; vinyl ethers; vinyl halides; vinyl phosphoric acids; vinyl sulfonic acids; vinylic anhydrides; vinylidene halides; fluorophenyl (meth)acrylates; vinyltrimethylsilanes; and any combination thereof.

The various co-monomers are typically selected from the group of: vinyl aromatic (e.g., styrene), alkyl methacrylic (e.g., methyl methacrylate), and acrylonitrile monomers. These co-monomers help to adjust the solubility of the liquid rubber in the uncured liquid thermoset resins. In certain embodiments of the present invention, suitable monomers and oligomers include, laurylmethylacrylate; epoxy resin; acrylic (methylacrylic) oligomers; reactive polysiloxane oligomers; fluorinated acrylate/methacrylate; and trimethylolpropanetriacylate/methacrylate/tri/tetra-allylether.

Other Additives

The compositions of the invention can include other suitable additives including, but not limited to, plasticizers, internal release agent, lubricants, antioxidants, processing aids, UV stabilizers, anti-static agents, flame retardants etc. One of skill in the art can readily select these materials and their amounts based on the properties desired. The materials, if solid, are typically of dimensions that do not interfere with the ability of the polymeric material or the polymerizable liquid to flow into the mold cavities.

Component Group B: Plasticizers

As used herein, the term “plasticizer” is meant to refer to a compound capable of reducing the Tg of polymeric composition when blended therewith. Examples of suitable plasticizers suitable for use in the invention include, but are not limited to, adipic acid derivatives, such as diisodecyl adipate and dinonyl adipate; azelaic acid derivatives, such as diisotyl azeleate and di-n-hexyl azelate; benzoic acid derivatives, such as diethylene glycol dibenzoate and polyethylene glycol 200 dibenzoate; epoxy derivatives, such as epoxidized soy bean oil; Glycerol derivatives such as glycerol triacetate; isophthalic acid derivatives, such as dimethyl isophthalate; myristic acid derivatives, such as isopropyl myristate; oleic acid derivatives, such as propyloleate and tetrahydrofurfuryloleate; paraffin derivatives, such as chloroparaffin); phosphoric acid derivatives, such as triphenyl phosphate; phthalic acid derivatives, such as diisooctyl phthalate and diisodevyl phthalate; ricinoleic acid derivatives, such as propylene glycol ricinoleate; sebacic acid derivates, such as dibutyl sebacate; stearic acid derivatives, such as butyl stearate and propylene glycol monostearate; succinic acid derivatives, such as diethyl succinate; and sulfonic acid derivatives, such as ortho- and para-toluenesulfonamide.

Component Group C: Internal Release Agents

As used herein, the term “internal release agent”, which is synonymous with “internal mold release agent” used herein, refers to a compound, which when blended in a polymeric composition, is capable of reducing adhesion of the polymeric composition to a surface. While not wishing to be bound to a particular theory of operation, it is believed that the internal release agents of the present invention migrate to the interface between the nanoimprint mold and the nanoimprint resist, thereby reducing the energy of adhesion of the nanoimprint resist composition for the nanoimprint mold surface. Examples of suitable internal mold release agents suitable for use in the invention include but are not limited to polysiloxane and perfluorinated surfactants; polysiloxane-containing polyether or polyesters; perfluorinated (methyl)acrylates; reactive and non reactive backbones; fluorinated agents, such as ZONYL FSE (Dupont), ZONYL FS-62 (Dupont), FC-170-C (3M), and FC-95 (3M); Siloxane based agents, such as GP-187, GP-277, GP-287 (Innovative Polymer technology), and 55-NC (Dexter); siloxane containing polymers, as well as combinations thereof.

Component Group D: Compatibilizers, Lubricants, and Stabilizers

Other additives suitable for use in the invention, include, but are not limited to reactive ion etching (“RIE”) resistance, antistatic agents, stabilizers, compatibilizers, flame retardants, and lubricants. These additional additives can be included in the compositions of the invention for improving other properties of the resists.

Initiators

Examples of initiators suitable for use in compositions of the invention include, but are not limited to, thermal initiators, such as benzyl peroxide (BPO) and azobisisobutyronitrile (AIBN); and UV and other radiation initiators, such as benzophenone, 2-hydroxy-2-methyl-1-phenyl-1-propanone, and 1-hydroxydhexyl phenyl ketone.

Many suitable polymeric compositions useful in the present invention are composed of at least one of each of the components described above in Component Groups A, B, C and D. In certain embodiments of the present invention, the nanoimprint resists include from about 20 weight percent to 100 weight percent of the polymeric composition, up to about 80 weight percent of a plasticizer, and up to about 30 weight percent of a mold release agent. In other embodiments, the nanoimprint resists include from about 1 weight percent to about 50 weight percent of an oligomer; from about 0.01 weight percent to about 10 weight percent of a crosslinking agent; from about 50 weight percent to about 90 weight percent of a monomer; and from about 0.01 weight percent to about 2 weight percent of a photoinitiator. In certain of these embodiments, the polymeric compositions are capable of providing sub-50 nanometer structures in the nanoimprint resists. Desirably, the polymeric materials in these embodiments are above their glass transition temperature upon removal of the mold during the nanoimprinting process.

In certain embodiments there are provided thin films that include a nanoimprint resist comprising a polymeric composition capable of being deformed by a mold at a temperature of less than 200° C., said mold being capable of forming a plurality of structures having at least one dimension less than 200 nm, said polymeric composition being capable of retaining said plurality of structures upon removal of said mold. In certain of these embodiments, the nanoimprint resist further include a plasticizer, a mold release agent, a monomer, a crosslinker, an additive, or any combination thereof. In particular, there are provided several embodiments where the thin films are composed of nanoimprint resists that include from about 20 weight percent to 100 weight percent of the polymeric composition, up to about 80 weight percent of a plasticizer, and up to about 30 weight percent of a mold release agent.

In another embodiment of the present invention, the polymeric composition includes from about 1 weight percent to about 50 weight percent of units derived from an oligomer; from about 0.01 weight percent to about 10 weight percent of units derived from a crosslinking agent; and from about 50 weight percent to about 90 weight percent of units derived from a monomer. Typically, these polymeric compositions are capable of being deformed at a temperature of less than about 100° C., and typically capable of being deformed at a temperature above about 10° C. Accordingly, in certain embodiments, suitable thermoplastic compositions can provide nanoimprint resist having a glass transition temperature below about 10° C. In these embodiments, the polymeric composition typically includes at least one of a photocurable polymeric composition, a thermoplastic polymeric composition, a thermosettable polymeric composition, or any combination thereof.

In another embodiment of the present invention there is provided a nanoimprint resist, which includes a polymeric composition capable of being deformed by a mold at a temperature of less than 200° C., the mold capable of forming a plurality of structures having at least one dimension less than 200 nm, the polymeric composition capable of retaining said plurality of structures upon removal of said mold. In this embodiment, the nanoimprint resists is provided by any of the polymeric compositions provided herein.

All ranges described herein are inclusive and combinable.

### EXAMPLES

Examples 1-8 disclose various compositions that are useful in the present invention. The compositions can be prepared according to well known methods in the art.

### Example 1

A polymeric composition is composed of the following components.

| component | weight percent |
|---|---|
| poly(butyl methacrylate) | 20%-99.9% |
| dioctyl phthalate | 0-79.9% |
| GP-277 | 0.1-30% |

### Example 2

A polymeric composition is composed of the following components.

| component | weight percent |
|---|---|
| poly(methylhexadecylsiloxane) | 50%-100% |
| polyethylene glycol 200 dibenzoate | 0-50% |

### Example 3

A polymeric composition is composed of the following components.

| component | weight percent |
|---|---|
| polystyrene | 20%-99.9% |
| diisodecyl adipate | 0%-79.9% |
| GP-187 | 0.01%-30% |

### Example 4

A polymeric composition is composed of the following components.

| component | weight percent |
|---|---|
| poly(octadecyl methacrylate) | 90-99% |
| triphenyl phosphate | 0%-10% |
| FS-62 | 0%-1% |

### Example 5

A polymeric composition is composed of the following components.

| component | weight percent |
|---|---|
| poly(vinylchloride-co-vinylacetate) | 20%-100% |
| diisodevyl phthalate | 0%-80% |
| GP-187 | 0%-30% |

### Example 6

A composition of the invention comprises the following components.

| component | weight percent |
|---|---|
| polyvinylacetate | 20%-100% |
| diisodevyl phthalate | 0%-80% |
| siloxane containing polymer | 0%-30% |

### Example 7

A composition of the invention comprises the following components.

| component | weight percent |
|---|---|
| Divinylbenzene (“DVB”) | 28% |
| polyvinylacetate (PVAc) | 68% |
| GP-187 | 2% |
| AIBN | 2% |

### Example 8

A composition of the invention comprises the following components.

| component | weight percent |
|---|---|
| Acrylic polysiloxane | 73% |
| TMPTA | 11% |
| Laurylmethylacrylate | 12% |
| Iragcure184 | 4% |

Although the present invention has been described in considerable detail with reference to certain preferred embodiments and versions, other versions and embodiments are possible. Therefore, the scope of the appended claims should not be limited to the description of the versions and embodiments expressly disclosed herein.

What is claimed is:

1. A method for forming a pattern in a film carried on a substrate, said method comprising;
obtaining a mold of a material, which mold is hard relative to the film,
the film comprising a polymeric composition capable of being deformed by said mold at a temperature of less than 200° C.;
the mold having first and second protruding features spaced apart from each other and a recess formed thereby, fthe first and second features and the recess having a shape forming a mold pattern and providing at least one mold pattern lateral dimension which is less than 200 nm;
urging the mold into the film under a molding pressure;
the thickness of the film under the protruding features of the mold being reduced, thereby forming the mold pattern in the film;
removing the mold from the film; and
removing from the film the areas of reduced thickness, thereby exposing portions of the surface of the substrate which underlie the thin region such that the exposed portions of the surface of the substrate substantially replicate the mold pattern and have at least one lateral dimension which is less than 200 nm.

2. The method of claim 1, wherein the polymeric composition comprises a homopolymer, a copolymer, a random polymer, a block polymer, a grafted polymer, a telechelic polymer, a star polymer, a dendrimer, or any combination thereof.

3. The method of claim 1, wherein the polymeric composition comprises: poly(methyl methacrylate), poly(bisphenol-A carbonate), poly(methylhexadecylsiloxane), poly(methylacrylate), poly(n-butyl acrylate), poly(octadecyl methacrylate), poly(isobutyl methacrylate), poly(butyl methacrylate), poly(vinylacetate), poly(vinyl stearate), poly(ethylene oxide), polycaprolactone, poly(α-methylstyrene), poly(vinyl stearate)/poly(methyl methacrylate), poly(methylhexadecylsiloxane)/poly(methyl methacrylate), poly(octadecyl methacrylate)/poly(methyl methacrylate), poly(butyl methacrylate-co-isobutylmethacrylate), poly(butyl methacrylate-co-methyl methacrylate), poly(dimethylsiloxane-co-alpha-methylstyrene), poly(ethylene-co-vinylacate)-graft(t-maleic anhydride), poly(vinyl chloride-co-vinylacetate), poly(vinyl chloride-co-isobutylvinylether), poly(chlorotrifluorethylene-co-vinyldiene fluoride), or any combination thereof.

4. The method of claim 1, wherein the polymeric composition comprises an oligomer, said oligomer comprising an epoxy resin, an acrylic (methylacrylic) oligomer, a reactive polysiloxane oligomer, or any combination thereof.

5. The method of claim 1, wherein the polymeric composition further comprises a monomer, said monomer comprising a C₈-C₂₀ alkyl methacrylate, a fluorinated alkyl (meth)acrylate monomer, or any combination thereof.

6. The method of claim 1, wherein the polymeric composition further comprises a crosslinker, said crosslinker comprising DVB, TMPTA,, or any combination thereof.

7. A method of forming a plurality of structures having at least one dimension less than 200 nm, which comprises the step of imprinting a nanoimprint resist using a mold, said nanoimprint resist comprising a polymeric composition capable of being deformed by said mold at a temperature of less than 200° C., said polymeric composition capable of retaining said plurality of structures upon removal of said mold.

8. The method of claim 7, wherein said polymeric composition is capable of being deformed at a temperature of less than about 100° C.

9. The method of claim 7, wherein said polymeric composition comprises a photocurable polymeric composition, a thermoplastic polymeric composition, a thermosettable polymeric composition, or any combination thereof.

10. The method of claim 9, wherein said photocurable polymeric composition is capable of curing in less than about 2 seconds.

11. The method of claim 9, wherein said photocurable polymeric composition has a viscosity of greater than about 2 poise at 25° C.

12. The method of claim 11, wherein said photocurable polymeric composition has a viscosity in the range of about 10 poise to about 30 poise.

13. The method of claim 9, wherein said photocurable polymeric composition comprises an oligomer, said oligomer comprising silicon atoms.

14. The method of claim 9, wherein said photocurable polymeric composition is capable of crosslinking in less than about 2 seconds.

15. The method of claim 9, wherein said photocurable polymeric composition comprises up to about 90 weight percent monomer.

16. The method of claim 7, wherein said nanoimprint resist further comprises a plasticizer, a mold release agent, a monomer, a crosslinker, an additive, or any combination thereof.

17. The method of claim 7, wherein said nanoimprint resist comprises from about 20 weight percent to 100 weight percent of said polymeric composition, up to about 80 weight percent of a plasticizer, and up to about 30 weight percent of a mold release agent.

18. The method of claim 7, wherein said nanoimprint resist comprises;
a) from about 1 weight percent to about 50 weight percent of an oligomer;
b) from about 0.01 weight percent to about 10 weight percent of a crosslinking agent;
c) from about 50 weight percent to about 90 weight percent of a monomer; and
d) from about 0.01 weight percent to about 2 weight percent of a photoinitiator.

19. The method of claim 7, wherein sub-50 nanometer structures are formed.

20. The method of claim 7, wherein said polymeric material is above its glass transition temperature upon removal of said mold.

21. A thin film, comprising:
a) a nanoimprint resist comprising a polymeric composition capable of being deformed by a mold at a temperature of less than 200° C., said mold being capable of forming a plurality of structures having at least one dimension less than 200 nm, said polymeric composition being capable of retaining said plurality of structures upon removal of said mold.

22. The thin film of claim 21, wherein said nanoimprint resist further comprises a plasticizer, a mold release agent, a monomer, a crosslinker, an additive, or any combination thereof.

23. The thin film of claim 21, wherein said nanoimprint resist comprises from about 20 weight percent to 100 weight percent of said polymeric composition, up to about 80 weight percent of a plasticizer, and up to about 30 weight percent of a mold release agent.

24. The thin film of claim 21, wherein said polymeric composition comprises;
a) from about 1 weight percent to about 50 weight percent of units derived from an oligomer;
b) from about 0.01 weight percent to about 10 weight percent of units derived from a crosslinking agent; and
c) from about 50 weight percent to about 90 weight percent of units derived from a monomer.

25. The thin film of claim 21, wherein said polymeric composition is capable of being deformed at a temperature of less than about 100° C.

26. The thin film of claim 25, wherein said polymeric composition is capable of being deformed at a temperature above about 10° C.

27. The thin film of claim 21, wherein said polymeric composition comprises a photocurable polymeric composition, a thermoplastic polymeric composition, a thermosettable polymeric composition, or any combination thereof.

28. The thin film of claim 21, wherein said nanoimprint resist comprises a glass transition temperature below about 10° C.

29. A nanoimprint resist, comprising a polymeric composition capable of being deformed by a mold at a temperature of less than 200° C., said mold capable of forming a plurality of structures having at least one dimension less than 200 nm, said polymeric composition capable of retaining said plurality of structures upon removal of said mold.
